(19) United States
(12) Patent Application Publication
(10) Pub. No.: US 2015/0176125 A1
(43) Pub. Date: Jun. 25, 2015

(54) SUBSTRATE PROCESSING APPARATUS

(71) Applicant: TOKYO ELECTRON LIMITED, Tokyo (JP)

(72) Inventors: Toshihisa NOZAWA, Miyagi (JP); Takehisa SAITO, Miyagi (JP); Koji YAMAGISHI, Miyagi (JP)

(73) Assignee: TOKYO ELECTRON LIMITED, Tokyo (JP)

(21) Appl. No.: 14/574,610

(22) Filed: Dec. 18, 2014

(30) Foreign Application Priority Data
Dec. 20, 2013 (JP) 2013-264072

(51) Int. Cl. C23C 16/455; C23C 16/458

(52) U.S. Cl. CPC C23C 16/45559; C23C 16/458

(57) ABSTRACT

Disclosed is a substrate processing apparatus for processing a processing target object by a processing gas. The substrate processing apparatus includes: a processing container configured to accommodate the processing target object; a mounting unit provided within the processing container to place the processing target object thereon; a processing gas supply unit provided in a side wall of the processing container to supply the processing gas into the processing container; and a processing gas diffusion mechanism provided outside the processing gas supply unit. The processing gas diffusion mechanism includes a first diffusion chamber and a second diffusion chamber which are provided in multiple stages, and the first diffusion chamber is located above the second diffusion chamber, and the first diffusion chamber and the second diffusion chamber communicate with each other through a plurality of processing gas communication paths.

### CROSS-REFERENCE TO RELATED APPLICATIONS

This application is based on and claims priority from Japanese Patent Application No. 2013-264072, filed on Dec. 20, 2013, with the Japan Patent Office, the disclosure of which is incorporated herein in its entirety by reference.

### TECHNICAL FIELD

The present disclosure relates to a substrate processing apparatus such as, for example, a plasma processing apparatus configured to process a processing target object by, for example, turning a processing gas into plasma.

### BACKGROUND

In manufacturing a semiconductor device, various processing processes are performed on a substrate (a semiconductor wafer which may also be simply referred to as a “wafer” below), and processing apparatuses for performing the respective processing processes are used. For example, as a plasma processing apparatus for performing a predetermined plasma processing on a processing target object such as a semiconductor wafer, a plasma processing apparatus which introduces microwaves into a processing container to generate plasma is known. In the plasma processing apparatus using microwaves, plasma with a low electron temperature and a high density may be generated under a low pressure within the processing container, and, for example, a film-forming processing or an etching processing is performed by the generated plasma.

As for the plasma processing apparatus described above, for example, Japanese Laid-Open Patent Publication No. 2008-251674 proposes a plasma processing apparatus. In the plasma processing apparatus disclosed in Japanese Laid-Open Patent Publication No. 2008-251674, a processing gas and microwaves are supplied into a processing container so that the processing gas is turned into plasma by the microwaves. Then, a wafer is carried into the apparatus and a plasma processing is performed on the wafer using the processing gas turned into the plasma in a state where the wafer is placed within the apparatus.

In the plasma processing apparatus disclosed in Japanese Laid-Open Patent Publication No. 2008-251674, the processing gas supplied into the processing container is introduced into the apparatus from two portions of the processing container, that is, a ceiling portion and a side wall portion. Specifically, a processing gas introducing unit configured to introduce the processing gas from the side wall portion of the processing container includes a buffer chamber (a diffusion chamber) formed annularly within the side wall, and a plurality of side wall gas ejecting holes formed in a circumferential direction at regular intervals to face a plasma generating space (a space within the processing container) from the buffer chamber. The processing gas is supplied to the buffer chamber through a gas supply tube from a processing gas supply source.

As described above, various technologies have conventionally been conceived to efficiently and uniformly introduce a processing gas into a processing container in a substrate processing apparatus such as, for example, a plasma processing apparatus.

### SUMMARY

The present disclosure provides a substrate processing apparatus for processing a processing target object by a processing gas. The substrate processing apparatus includes: a processing container configured to accommodate the processing target object; a mounting unit provided within the processing container to place the processing target object on the mounting unit thereon; a processing gas supply unit provided in a side wall of the processing container to supply the processing gas into the processing container; and a processing gas diffusion mechanism provided outside the processing gas supply unit. The processing gas diffusion mechanism includes a first diffusion chamber and a second diffusion chamber which are provided in multiple stages, and the first diffusion chamber is located above the second diffusion chamber, and the first diffusion chamber and the second diffusion chamber communicate with each other through a plurality of processing gas communication paths.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view schematically illustrating a configuration of a plasma processing apparatus according to an exemplary embodiment.

FIG. 2 is a plan view of a first diffusion chamber.

FIG. 3 is a plan view of a second diffusion chamber.

FIG. 4 is a schematic enlarged view for explaining a configuration of a processing gas communication path.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

For example, in the plasma processing apparatus disclosed in Japanese Laid-Open Patent Publication No. 2008-251674, the gas supply tube is connected to only a part of the annular buffer chamber to supply the processing gas from the processing gas supply source to the buffer chamber. Thus, in the buffer chamber, a flow or a pressure of a gas may vary between a portion close to the processing gas supply tube and a portion far from the processing gas supply tube so that the gas may be stagnant. That is, the pressure of the processing gas within the buffer chamber is not sufficiently uniformized, so that the introduction of the processing gas into the processing container may become non-uniform.

The present disclosure has been made in consideration of these problems, and an object of the present disclosure is to uniformize a processing gas introduced into a processing container of a substrate processing apparatus by optimizing a flow of the gas within a diffusion chamber through which the processing gas passes.

In order to achieve the object, there is provided a substrate processing apparatus for processing a processing target object by a processing gas. The substrate processing apparatus includes: a processing container configured to accommodate the processing target object; a mounting unit provided within the processing container to place the processing target object thereon; a processing gas supply unit provided in a side wall of the processing container to supply the processing gas into the processing container; and a processing gas diffusion mechanism provided outside the processing gas supply unit. The processing gas diffusion mechanism includes a first diffusion chamber and a second diffusion chamber which are provided in multiple stages, and the first diffusion chamber is located above the second diffusion chamber, and the first diffusion chamber and the second diffusion chamber communicate with each other through a plurality of processing gas communication paths.

According to the present disclosure, the processing gas diffusion mechanism including the first diffusion chamber and the second diffusion chamber in multi stages is provided outside the processing gas supply unit so that the processing gas is uniformized, and the uniform processing gas is introduced into the processing container. Accordingly, a substrate processing (e.g., a plasma film-forming processing) is uniformly performed by the processing gas within the processing container.

The first diffusion chamber and the second diffusion chamber are annularly configured to surround the processing container, and gas introducing ports are provided in the plurality of processing gas communication paths, respectively, to eject the processing gas into the second diffusion chamber in one predetermined direction.

The plurality of processing gas communication paths is obliquely provided so that the processing gas ejected from the gas introducing ports is ejected in a predetermined direction along a circumferential direction within the second diffusion chamber.

A viscous flow of the processing gas is formed within the second diffusion chamber by the processing gas ejected from the gas introducing ports.

According to the present disclosure, when the processing gas is introduced into the processing container of the substrate processing apparatus, the flow of the gas may be optimized within the diffusion chamber through which the processing gas passes so as to uniformize the processing gas introduced into the processing container.

Hereinafter, exemplary embodiments of the present disclosure will be described with reference to drawings. In the present specification and the drawings, components having substantially the same functional configuration will be denoted by the same reference numerals and redundant descriptions will be omitted. In the present exemplary embodiment, a plasma processing apparatus 1 is exemplified as a substrate processing apparatus. In the plasma processing apparatus 1, a plasma chemical vapor deposition (CVD) processing is performed on the surface of a wafer W as a processing target object to form an SiN film (a silicon nitride film) on the surface of the wafer W.

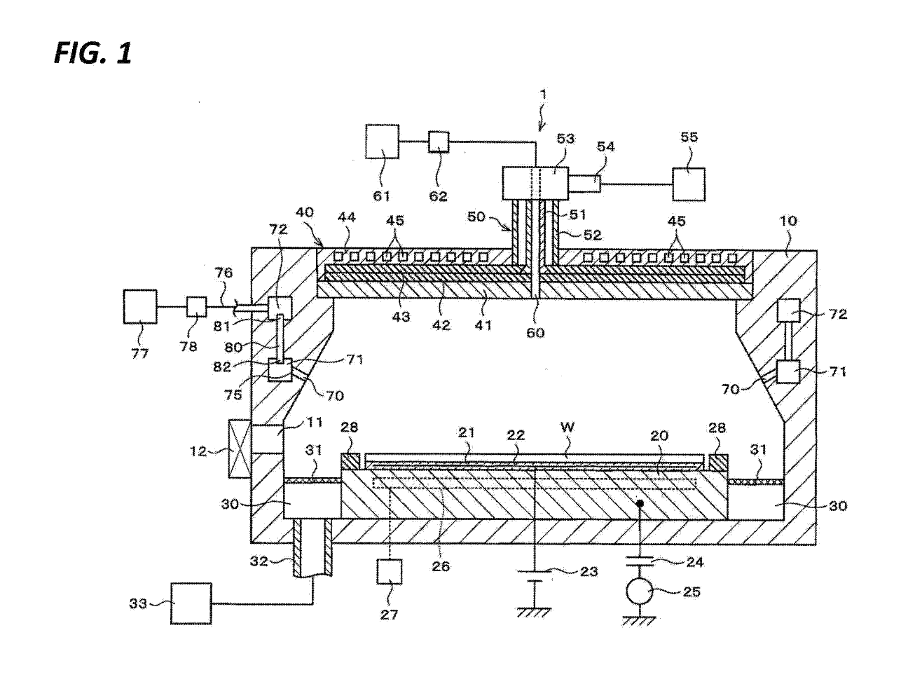

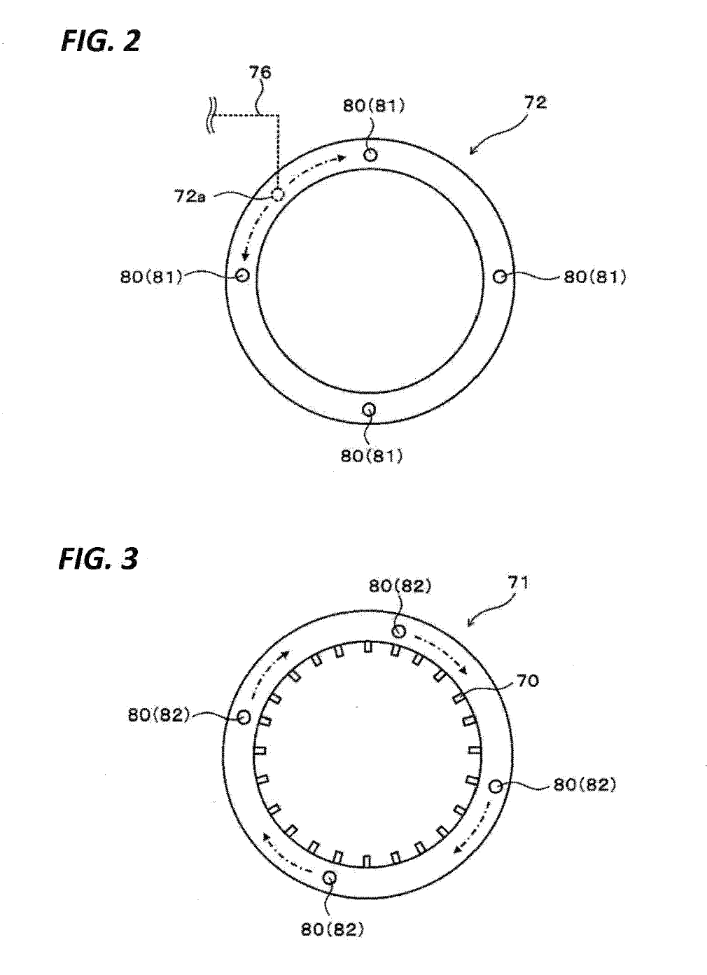

As illustrated in FIG. 1, the plasma processing apparatus 1 includes a processing container 10. The processing container 10 has a substantially cylindrical shape with an opened ceiling, and a radial line slot antenna 40 to be described later is disposed on the opening of the ceiling A carry-in/out port 11 of the wafer W is formed as an opening on the side wall of the processing container 10, and a gate valve 12 is provided in the carry-in/out port 11. The processing container 10 is configured such that its inside may be sealed. The configuration of the carry-in/out port 11 or the gate valve 12 is simply illustrated in FIG. 1, and, for example, a specific configuration thereof will be described later with reference to, for example, FIG. 2. A metal such as aluminum or stainless steel is used for the processing container 10, and the processing container 10 is grounded.

A mounting stage 20 is provided on the bottom surface within the processing container 10, as a mounting unit on which the wafer W is placed. The mounting stage 20 has a cylindrical shape, and is made of, for example, aluminum.

An electronic chuck 21 is provided on the top surface of the mounting stage 20. The electronic chuck 21 is constituted by an electrode 22 interposed between insulating materials. The electrode 22 is connected to a direct current (DC) power supply 23 provided outside the processing container 10. A Coulomb force may be generated on the surface of the mounting stage 20 by the DC power supply 23 so as to electrostatically attract the wafer W on the mounting stage 20.

The mounting stage 20 may be connected to a high frequency power supply 25 for RF bias through a capacitor 24. The high frequency power supply 25 outputs high frequency waves of a predetermined frequency which is suitable for controlling energy of ions to be drawn into the wafer W, for example, 13.65 MHz, with a predetermined power.

A temperature control mechanism 26 is provided within the mounting stage 20 to circulate, for example, a cooling medium. The temperature control mechanism 26 is connected to a liquid temperature control unit 27 configured to control the temperature of the cooling medium. The temperature of the cooling medium is controlled by the liquid temperature control unit 27 so as to control the temperature of the mounting stage 20. As a result, the wafer W placed on the mounting stage 20 may be maintained at a predetermined temperature. A gas path (not illustrated) is formed in the mounting stage 20 to supply a heat transfer medium, for example, He gas, to the rear surface of the wafer W at a predetermined pressure (a background pressure).

An annular focus ring 28 is provided on the top surface of the mounting stage 20 to surround the wafer W on the electronic chuck 21. An insulating material such as, for example, ceramic or quartz, is used for the focus ring 28, and the focus ring 28 acts to improve the uniformity of a plasma processing.

Lift pins (not illustrated) are provided below the mounting stage 20 to support and lift the wafer W from the bottom side. The lift pins are adapted to be inserted into through holes (not illustrated) formed in the mounting stage 20 to protrude from the top surface of the mounting stage 20.

An annular exhaust space 30 is formed around the mounting stage 20, between the mounting stage 20 and the side wall of the processing container 10. An annular baffle plate 31 formed with a plurality of exhaust holes is provided above the exhaust space 30 to uniformly evacuate the inside of the processing container 10. An exhaust pipe 32 is connected to the bottom surface of the processing container 10 as the bottom portion of the exhaust space 30. The number of exhaust pipes 32 may be freely set. A plurality of exhaust pipes 32 may be formed in the circumferential direction. The exhaust pipe 32 is connected to an exhaust device 33 provided with, for example, a vacuum pump. The exhaust device 33 may decompress the atmosphere within the processing container 10 to a predetermined vacuum degree.

A radial line slot antenna 40 is provided in the opening of the ceiling of the processing container 10 to supply microwaves for plasma generation. The radial line slot antenna 40 includes a microwave transmitting plate 41, a slot plate 42, a slow wave plate 43, and a shield cover 44.

The microwave transmitting plate 41 is hermetically provided in the ceiling opening of the processing container 10 through a sealing member (not illustrated) such as, for example, an O ring. Accordingly, the inside of the processing container 10 is hermetically maintained. A dielectric material such as, for example, quartz, Al₂O₃, or AlN is used for the microwave transmitting plate 41. The microwave transmitting plate 41 transmits microwaves.

The slot plate 42 is provided on the top surface of the microwave transmitting plate 41 to be opposite to the mounting stage 20. A plurality of slots is formed in the slot plate 42, and the slot plate 42 serves as an antenna. A conductive material, such as, for example, copper, aluminum, or nickel is used for the slot plate 42.

The slow wave plate 43 is provided on the top surface of the slot plate 42. A low-loss dielectric material such as, for example, quartz, Al₂O₃, or AlN is used for the slow wave plate 43, and the slow wave plate 43 shortens the wavelength of microwaves.

The shield cover 44 is provided on the top surface of the slow wave plate 43 to cover the slow wave plate 43 and the slot plate 42. A plurality of annular flow paths 45 is provided within the shield cover 44 to circulate, for example, a cooling medium. The microwave transmitting plate 41, the slot plate 42, the slow wave plate 43, and the shield cover 44 are controlled to a predetermined temperature by the cooling medium flowing in the flow paths 45.

A coaxial waveguide 50 is connected to the central portion of the shield cover 44. The coaxial waveguide 50 includes an inner conductor 51 and an outer tube 52. The inner conductor 51 is connected to the slot plate 42. The slot plate 42 side of the inner conductor 51 is conically shaped to efficiently propagate microwaves to the slot plate 42.

The coaxial waveguide 50 is connected to a mode converter 53 configured to convert microwaves into a predetermined vibration mode, a rectangular waveguide 54, and a microwave generator 55 configured to generate microwaves are connected, in this order from the coaxial waveguide 50 side. The microwave generator 55 generates microwaves having a predetermined frequency of, for example, 2.45 GHz.

With this configuration, the microwaves generated by the microwave generator 55 successively propagates through the rectangular waveguide 54, the mode converter 53, and the coaxial waveguide 50 to be supplied to the radial line slot antenna 40. The microwaves are compressed by the slow wave plate 43 to be reduced in wavelength, generate circular polarization waves in the slot plate 42 and then pass through the microwave transmitting plate 41 from the slot plate 42 to be radiated into the processing container 10. The processing gas is turned into plasma by the microwaves within the processing container 10, and the plasma processing of the wafer W is performed by the plasma.

A first processing gas supply tube 60 is provided in the ceiling of the processing container 10, that is, in the central portion of the radial line slot antenna 40. The first processing gas supply tube 60 penetrates the radial line slot antenna 40, and one end of the first processing gas supply tube 60 is opened in the bottom surface of the microwave transmitting plate 41. The first processing gas supply tube 60 penetrates the inside of the inner conductor 51 of the coaxial waveguide 50, and is further inserted through the inside of the mode converter 53 so that the other end of the first processing gas supply tube 60 is connected to a first processing gas supply source 61. Within the first processing gas supply source 61, for example, trisilylamine (TSA), N₂ gas, H₂ gas, and Ar gas are individually stored as the processing gases. Among them, TSA, N₂ gas, and H₂ gas are raw material gases for forming a SiN film, and Ar gas is a plasma excitation gas. Hereinafter, the processing gases may be referred to as a “first processing gas.” The first processing gas supply tube 60 is provided with a supply device group 62 that includes, for example, a valve or a flow rate control unit which controls the flow of the first processing gas.

As illustrated in FIG. 1, second processing gas supply tubes 70 are provided in the side wall of the processing container 10. The plurality of second processing gas supply tubes 70, for example, twenty four (24) second processing gas supply tubes 70, is provided at regular intervals along the circumference of the side wall of the processing container 10. One end of each of the second processing gas supply tubes 70 is opened on the side surface of the processing container 10 and the other end is connected to a second diffusion chamber 71. Each of the second processing gas supply tubes 70 is disposed obliquely so that one end of each of the second processing gas supply tubes 70 is located at the lower side than the other end.

The second diffusion chamber 71 is annularly provided within the side wall of the processing container 10, and is provided in common to the plurality of second processing gas supply tubes 70. A first diffusion chamber 72 is provided above the second diffusion chamber 71. That is, the annular first diffusion chamber 72 and the second diffusion chamber 71 are provided in multiple stages within the side wall of the processing container 10. The first diffusion chamber 72 and the second diffusion chamber 71 communicate with each other through a plurality of processing gas communication paths 80 provided at regular intervals along the circumference. In the present exemplary embodiment, a processing gas diffusion mechanism is constituted by the first diffusion chamber 72 and the second diffusion chamber 71.

Gas introducing ports 82 are provided in the processing gas communication paths 80, respectively, to eject the processing gas into the second diffusion chamber 71. Exhaust ports 75 are provided in the second diffusion chamber 71 to discharge a second processing gas into the processing container 10 through the second processing gas supply tubes 70.

A second processing gas supply source 77 is connected to the first diffusion chamber 72 through a supply tube 76. Within the second processing gas supply source 77, for example, trisilylamine (TSA), N₂ gas, H₂ gas, and Ar gas are individually stored as the processing gases. Hereinafter, the processing gases may be referred to as a “second processing gas.” The supply tube 76 is provided with a supply device group 78 that includes, for example, a valve or a flow rate control unit which controls the flow of the second processing gas.

The first processing gas is supplied from the first processing gas supply tube 60 toward the central portion of the wafer W, and the second processing gas is supplied from the second processing gas supply tubes 70 toward the periphery of the wafer W.

The first processing gas and the second processing gas to be supplied into the processing container 10 respectively from the first processing gas supply tube 60 and the second processing gas supply tubes 70 may be the same kind of gases or different kinds of gases, and may be supplied at independent flow rates, respectively or at an optional flow rate ratio.

Hereinafter, descriptions will be made on a plasma processing of a wafer W which is performed by the plasma processing apparatus 1 configured as described above. In the present exemplary embodiment, as described above, a plasma film-forming processing is performed on a wafer W to form a SiN film on the surface of the wafer W.

First, the gate valve 12 is opened to carry the wafer W into the processing container 10. The wafer W is placed on the mounting stage 20 by the lift pins. Here, the DC power supply 23 is turned ON to apply a DC voltage to the electrode 22 of the electronic chuck 21, and the wafer W is electrostatically attracted on the electronic chuck 21 by a Coulomb force of the electronic chuck 21. Then, the gate valve 12 is closed so as to seal the inside of the processing container 10, and the exhaust device 33 is operated to decompress the inside of the processing container 10 to a predetermined pressure, for example, 400 mTorr (53 Pa).

Then, the first processing gas is supplied into the processing container 10 from the first processing gas supply tube 60, and the second processing gas is supplied into the processing container 10 from the second processing gas supply tubes 70. Here, the flow rate of Ar gas supplied from the first processing gas supply tube 60 may be, for example, 100 sccm (mL/min), and the flow rate of Ar gas supplied from the second processing gas supply tubes 70 may be, for example, 750 sccm (mL/min).

As described above, when the first processing gas and the second processing gas are supplied into the processing container 10, the microwave generator 55 is operated to generate microwaves having a frequency of, for example, 2.45 GHz, with a predetermined power. The microwaves are radiated into the processing container 10 through the rectangular waveguide 54, the mode converter 53, the coaxial waveguide 50, and the radial line slot antenna 40. By the microwaves, the first processing gas and the second processing gas are turned into plasma within the processing container 10, and each processing gas in the plasma is dissociated. By the active species generated during the dissociation, a film-forming processing is performed on the wafer W. In this manner, a SiN film is formed on the surface of the wafer W.

While a plasma film-forming processing is performed on the wafer W, the high frequency power supply 25 may be turned ON to output high frequency waves of a frequency of, for example, 13.56 MHz, with a predetermined power. The high frequency waves are applied to the mounting stage 20 through the capacitor 24, so as to apply the RF bias to the wafer W. In the plasma processing apparatus 1, the electron temperature of the plasma may be maintained to be low. Thus, no damage is caused in the film, and further, molecules of the processing gas are likely to be dissociated by high-density plasma, thereby facilitating the reaction. Application of the RF bias in an appropriate range acts to draw ions in the plasma into the wafer W, thereby improving the denseness of the SiN film, and increasing traps in the film.

Then, when the SiN film is grown and formed on the wafer W to a predetermined thickness, the supply of the first processing gas and the second processing gas and radiation of the microwaves are stopped. Then, the wafer W is carried out from the processing container 10, and a series of plasma film-forming processings is completed.

Hereinafter, descriptions will be made on the configuration of the first diffusion chamber 72 and the second diffusion chamber 71 as a processing gas diffusion mechanism provided in the side wall of the processing container 10 according to the present exemplary embodiment, with reference to drawings. Hereinafter, in order to make descriptions mainly with the first diffusion chamber 72 and the second diffusion chamber 71, for example, peripheral devices are appropriately omitted in the reference drawings.

FIG. 2 is a horizontal cross-sectional view of the first diffusion chamber 72, and FIG. 3 is a horizontal cross-sectional view of the second diffusion chamber 71. As illustrated in FIG. 2, the first diffusion chamber 72 is annularly configured, and is connected to the second processing gas supply source 77 through the supply tube 76 in a predetermined portion 72a of the first diffusion chamber 72. That is, the second processing gas is supplied from the predetermined portion 72a into the first diffusion chamber 72. Thus, within the annular first diffusion chamber 72, a flow of the second processing gas occurs both clockwise and anti-clockwise (see, the dashed line arrows in FIG. 2).

As illustrated in FIGS. 2 and 3, the first diffusion chamber 72 and the second diffusion chamber 71 communicate with each other through the plurality of processing gas communication paths 80 such that the second processing gas within the first diffusion chamber 72 is introduced into the second diffusion chamber 71 through the processing gas communication paths 80. In the present exemplary embodiment, the processing gas communication paths 80 are assumed to be connected to four locations on the circumference of each of the annular first diffusion chamber 72 and the second diffusion chamber 71 at substantially regular intervals. In the first diffusion chamber 72, inlets of the processing gas communication paths are denoted by reference numeral 81, and in the second diffusion chamber 71, outlets of the processing gas communication paths 80 are illustrated as the gas introducing ports 82.

As illustrated in FIG. 3, the plurality of second processing gas supply tubes 70 is provided along the inner circumference in the second diffusion chamber 71. One end of each of the second processing gas supply tubes 70 is connected to the second diffusion chamber 71, and the other end is connected to be opened on the side surface of the processing container 10 (not illustrated in FIG. 3). In the present exemplary embodiment, the number of the second processing gas supply tubes 70 illustrated in the drawing is twenty four (24).

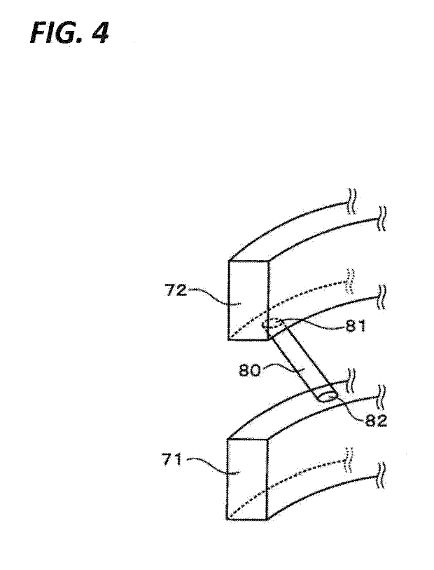

Here, FIGS. 2 and 3 are plan views illustrating the first diffusion chamber 72 and the second diffusion chamber 71 viewed from the same point thereabove, and the locations of the inlets 81 and the outlets (that is, the gas introducing ports 82) of the processing gas communication paths are out of alignment in the circumferential direction in plan view. This is because each of the processing gas communication paths 80 is configured obliquely in the annular circumferential direction with respect to the vertical direction. FIG. 4 is a schematic enlarged view for describing the configuration of each of the processing gas communication paths 80 obliquely configured as described above. In the present exemplary embodiment, the processing gas communication paths 80 are provided at four (4) locations on the circumference of the first diffusion chamber 72 and the second diffusion chamber 71, but all the processing gas communication paths 80 are inclined in the same direction. The inclination angle of the processing gas communication paths 80 may be freely changed and is appropriately set according to conditions such as, for example, the internal pressure of the first diffusion chamber 72 and the internal pressure of the second diffusion chamber 71.

As described above with reference to FIGS. 2 to 4, when the second processing gas is introduced from the first diffusion chamber 72 into the second diffusion chamber 71, the introduction is performed through the processing gas communication paths 80 configured obliquely in the annular circumferential direction. Here, all the processing gas communication paths 80 at the plurality of locations (four locations) are inclined in the same direction, so that the second processing gas is introduced from all the processing gas communication paths 80 in the same direction within the second diffusion chamber 71. Accordingly, a swirling flow of the second processing gas is formed within the second diffusion chamber 71 to flow in the annular one direction (the direction of the dashed line arrows in FIG. 3).

Here, the swirling flow of the second processing gas is formed within the second diffusion chamber 71 by forming the processing gas communication paths 80 to be inclined. However, the swirling flow of the second processing gas may be formed by a configuration in which the gas introducing ports 82 serving as the outlets of the processing gas communication paths 80 are formed in an inclined nozzle shape without forming the processing gas communication paths 80 to be inclined.

As described above, the swirling flow of the second processing gas is formed within the second diffusion chamber 71. The swirling flow may become a viscous flow by adjusting various conditions. Hereinafter, conditions for causing the second processing gas to flow as the viscous flow will be described.

In determining a viscous flow region of a fluid, a Knudsen number (Kn) expressed by the following equation (1) is known as a dimensionless constant expressing the flow of a low-density gas.

Kn=λ/L=k_{b}T/√2πσ²PL (1)

Here, λ is a mean free path (m), L is a representative length (m), T is a temperature (K), kB is a Boltzmann constant (J/K), P is a total pressure (Pa), and σ is a molecular diameter (m). In the present exemplary embodiment, the total pressure (P) refers to a pressure within the second diffusion chamber 71, and the representative length (L) refers to a representative dimension of the second diffusion chamber 71.

When the Knudsen number (Kn) is 0.01 or less in a region where molecules in a fluid are sufficiently colliding with each other, the region is defined as a viscous flow region. That is, a gas in the viscous flow region may be considered as a continuous fluid, and thus becomes a viscous flow. In equation (1), since values other than P and L for a swirling flow of the second processing gas are known, the swirling flow of the second processing gas may become a viscous flow within the second diffusion chamber 71 when the pressure within the second diffusion chamber 71 and the representative dimension of the second diffusion chamber 71 are properly adjusted.

In the processing gas diffusion mechanism (that is, the first diffusion chamber 72 and the second diffusion chamber 71) configured as described above, the second processing gas is introduced from one portion in the step of supplying the second processing gas from the second processing gas supply source 77 to the first diffusion chamber 72. Therefore, the second processing gas may not be uniformized. Meanwhile, in the step of introducing the second processing gas from the first diffusion chamber 72 to the second diffusion chamber 71, the second processing gas is introduced to the second diffusion chamber 71 through the processing gas communication paths 80 provided at a plurality of locations. Therefore, the second processing gas may be uniformized within the second diffusion chamber 71. Then, since the uniform second processing gas is supplied into the processing container 10 from the second diffusion chamber 71 through the plurality of second processing gas supply tubes 70 (e.g., twenty four (24) second processing gas supply tubes 70), a substrate processing by the second processing gas (a plasma film-forming processing in the present exemplary embodiment) may be uniformly performed.

As described above, since the plurality of processing gas communication paths 80 is inclined in the same direction along the circumferential direction, the second processing gas is introduced into the second diffusion chamber 71 to form a swirling flow along a predetermined direction (clockwise in FIG. 3). Especially, when the swirling flow is a viscous flow, stagnation does not occur in the flowing of the second processing gas within the second diffusion chamber 71, and the second processing gas is uniformized highly precisely. Thus, the second processing gas to be supplied into the processing container 10 is also uniformized precisely. Accordingly, uniformity of the substrate processing within the processing container 10 is achieved with a higher precision.

In the above-described exemplary embodiment, the processing gas communication paths 80 connecting the first diffusion chamber 72 to the second diffusion chamber 71 are provided at four (4) locations at regular intervals, and the second processing gas supply tubes 70 are provided at twenty four (24) locations to supply the second processing gas from the second diffusion chamber 71 into the processing container 10, but the present disclosure is not limited thereto. The processing gas communication paths 80 may be provided at a plurality of locations at which a swirling flow of the second processing gas may be properly uniformized within the second diffusion chamber 71. Also, a plurality of second processing gas supply tubes 70 may be configured to allow the second processing gas to be uniformly supplied into the processing container 10 to uniformly perform the substrate processing.

In the above-described exemplary embodiment, the plasma processing apparatus using microwaves is exemplified in which a plasma CVD processing is performed on the surface of a wafer W as a processing target object to form a SiN film on the surface of the wafer W, but an application scope of the present disclosure is not limited thereto. That is, the present disclosure may be applied to various apparatuses for processing substrates in which a processing gas is introduced into a processing container to process a substrate. For example, the present disclosure may also be applied to a vapor deposition device configured to perform vapor deposition on a substrate without using microwaves, or a cleaning device configured to clean a substrate by using a processing gas. The processing target object in the present disclosure may be any one of a glass substrate, an organic EL substrate, and a substrate for a flat panel display (FPD).

The present disclosure may be applied to, for example, a substrate processing apparatus such as a plasma processing apparatus in which a processing gas is turned into plasma to process a processing target object.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus for processing a processing target object by a processing gas, the substrate processing apparatus comprising:
a processing container configured to accommodate the processing target object;
a mounting unit provided within the processing container to place the processing target object thereon;
a processing gas supply unit provided in a side wall of the processing container to supply the processing gas into the processing container; and
a processing gas diffusion mechanism provided outside the processing gas supply unit,
wherein the processing gas diffusion mechanism includes a first diffusion chamber and a second diffusion chamber which are provided in multiple stages, and
the first diffusion chamber is located above the second diffusion chamber, and the first diffusion chamber and the second diffusion chamber communicate with each other through a plurality of processing gas communication paths.

2. The substrate processing apparatus of claim 1, wherein the first diffusion chamber and the second diffusion chamber are annularly configured to surround the processing container, and
gas introducing ports are provided in the plurality of processing gas communication paths, respectively, to eject the processing gas into the second diffusion chamber in one predetermined direction.

3. The substrate processing apparatus of claim 2, wherein the plurality of processing gas communication paths is obliquely provided so that the processing gas ejected from the gas introducing ports is ejected in a predetermined direction along a circumferential direction within the second diffusion chamber.

4. The substrate processing apparatus of claim 2, wherein a viscous flow of the processing gas is formed within the second diffusion chamber by the processing gas ejected from the gas introducing ports.
